(19) United States
(12) Patent Application Publication
(10) Pub. No.: US 2009/0325386 A1
(43) Pub. Date: Dec. 31, 2009

(54) Process and System For Varying the Exposure to a Chemical Ambient in a Process Chamber

(75) Inventors: Daniel J. Devine, Los Gatos, CA (US); Rudy Santo Tomas Cardema, San Jose, CA (US); Shuen Chun Choy, San Francisco, CA (US); Carl J. Galewski, Santa Cruz, CA (US); Yao Zhi Hu, San Jose, CA (US); Bruce W. Peuse, San Carlos, CA (US); Hung Thanh Phan, San Jose, CA (US)

Correspondence Address: DORITY & MANNING, P.A., POST OFFICE BOX 1449, GREENVILLE, SC, 29602-1449, US

(73) Assignee: MATTSON TECHNOLOGY, INC., Fremont, CA (US)

(21) Appl. No.: 12/473,762

(22) Filed: May 28, 2009

Related U.S. Application Data
(60) Provisional application No. 61/058,103, filed on Jun. 2, 2008.

(51) Int. Cl. H01L 21/465; C23C 16/44; C23C 16/00; G01F 25/00

(52) U.S. Cl. 438/706; 438/758; 118/715; 118/724; 156/345.34; 156/345.37; 73/1.16; 257/E21.485

(57) ABSTRACT

A processing system is disclosed for conducting various processes on substrates, such as semiconductor wafers by varying the exposure to a chemical ambient. The processing system includes a processing region having an inlet and an outlet for flowing fluids through the chamber. The outlet is in communication with a conductance valve that is positioned in between the processing region outlet and a vacuum exhaust channel. The conductance valve rapidly oscillates or rotates between open and closed positions for controlling conductance through the processing region. This feature is coupled with the ability to rapidly pulse chemical species through the processing region while simultaneously controlling the pressure in the processing region. Of particular advantage, the conductance valve is capable of transitioning the processing region through pressure transitions of as great as 100:1 while chemical species are flowed through the processing region using equally fast control valves in a synchronous pulsed fashion.

### RELATED APPLICATIONS

The present application is based upon and claims priority to U.S. Provisional Patent Application Ser. No. 61/058,103 filed on Jun. 2, 2008.

### BACKGROUND

Various different devices and products are made by applying one or more thin-film processes onto a substrate. These thin-film processes may include deposition of a thin-film layer, etching of a thin-film layer, surface conditioning, or cleaning of surfaces and features created on surfaces of treated substrates. In one embodiment, for instance, solid materials are deposited onto a substrate from a gas or vapor under carefully controlled conditions by any one of a variety of processes generally known as chemical vapor deposition. In another embodiment, a solid layer is patterned by removing an area not protected by a masking or protective layer using an etching process driven by any combination of thermal, chemical or physical processes. In yet another embodiment, the state of a surface is chemically and/or physically modified so as to prepare the substrate for a subsequent treatment. This surface preparation process can include processes that result in a common termination of exposed chemical bonds such as hydroxyl or hydrogen termination or removal contaminates such as particles and residues. Types of products that are made through the above processes include various electronic components, such as solar cells, flat panel display devices, and integrated circuits.

In general, an integrated circuit refers to an electrical circuit contained on a single monolithic chip containing active and passive circuit elements. Integrated circuits are fabricated by diffusing, depositing, partially removing and removing successive layers of various materials in pre-selected patterns on a substrate. The materials can include semiconductor materials such as silicon, conductive materials such as metals, and low dielectric materials such as silicon dioxide. Of particular significance, the thin-film materials contained in integrated circuit chips are used to form almost all of the ordinary electronic circuit elements, such as resistors, capacitors, diodes, and transistors.

Integrated circuits are used in great quantities in electronic devices, such as digital computers, because of their small size, low power consumption, and high reliability. The complexity of integrated circuits range from simple logic gates and memory units to large arrays capable of complete video, audio and print data processing. Presently, however, there is a demand for integrated circuit chips to accomplish more tasks in a smaller space while having even lower energy requirements.

As stated above, integrated circuit chips are manufactured by successively depositing and patterning layers of different materials on a substrate. Typically, the substrate is made from a thin slice or wafer of silicon although other substrate materials can also be used. The active and passive components of the integrated circuit are then built on top of the substrate. The components of the integrated circuit can include layers of different conductive materials such as metals and semiconductor materials integrated with both low and high dielectric insulator materials. In attempting to improve integrated circuit chips, attention has been focused upon reducing the size of features created on substrates, while improving performance of devices formed by the fabricated features.

For instance, in the past, those skilled in the art have attempted to improve thin-film processes by controlling the manner in which gases were fed to a process chamber and contacted with a wafer or by controlling the manner in which the gases were exhausted from the chamber. Those skilled in the art have also attempted to incorporate various controls into a process chamber for carefully controlling temperatures and pressures. The present disclosure is directed to further improvements in systems and processes for fabricating integrated circuit chips and other similar devices.

In addition to fabricating integrated circuit chips, as will be described below, the systems and processes of the present disclosure are also well suited to producing various other products and devices. For example, the teachings of the present disclosure can be used to treat any suitable substrate. Other products that may be made in accordance with the present disclosure include, for instance, solar cells, panel displays, sensors, Micro-Electro-Mechanical Systems (MEMS), nanostructured surfaces, and any other suitable electronic components.

### SUMMARY

In general, the present disclosure is directed to an improved processing system for processing substrates, such as semiconductor wafers. The system of the present disclosure, for instance, can be used to carry out many different operations on a substrate including but not limited to: chemical vapor deposition including atomic layer deposition or plasma enhanced chemical vapor deposition; etching processes including plasma etching processes; and surface conditioning and cleaning. The system generally includes a process chamber that includes a conductance valve that can rapidly vary the conductance of the pre-exhaust connected to a process chamber. More particularly, the conductance valve provides the ability to very rapidly vary the pressure inside the chamber in order to affect gas transport speeds, gas species concentrations, and other process variables. The conductance valve in communication with the pre-exhaust of the process chamber is also particularly well suited for use in processes where chemical species are pulsed into the chamber.

For instance, in one embodiment, the present disclosure is directed to a system for processing substrates. The system includes a process chamber containing a substrate holder configured to hold a substrate, such as a semiconductor wafer. The process chamber can include a processing region defining an inlet and an outlet that enhances circulation of gases, vapors and the like through the process chamber. Optionally, the process chamber may be in communication with a thermal control device for regulating the temperature of substrates as they are processed. The thermal control device may comprise, for instance, a heated substrate pedestal, a plurality of heating lamps, or combinations thereof.

In accordance with the present disclosure, the system further includes a conductance valve in communication with the outlet of the processing region. The conductance valve includes a conductance-limiting element that oscillates so as to control the pressure in the processing region.

The conductance valve may comprise any suitable valve device. In one embodiment, for instance, the conductance valve includes the conductance-limiting element in operative association with a voice coil actuator and a flexible bellows that allows the voice coil actuator to operate isolated from the ambient of the process chamber. The voice coil actuator, for instance, can be placed in communication with an air bearing that in turn serves to control the oscillation of the conductance-limiting element.

In one embodiment, the conductance-limiting element can be positioned at the outlet of the processing region. Specifically, the conductance-limiting element of the conductance valve can oscillate towards and away from the outlet. The conductance-limiting element can form a sealing arrangement with the outlet of the processing region such that the outlet is closed when the conductance-limiting element is in a closed position. Alternatively, the conductance-limiting element may form a non-sealing engagement with the outlet. In this embodiment, for instance, even when the conductance-limiting element is in a closed position, the conductance-limiting element forms a gap in between a surface of the conductance-limiting element and the outlet. The gap, for instance, can be less than about 100 microns, such as less than about 30 microns, such as even less than about 10 microns.

In accordance with the present disclosure, the processing region of the process chamber can have a relatively small volume. For instance for substrates such as a 300 mm diameter wafer, the processing region can have a volume of less than about 2 liters, such as less than about 1 liter, such as less than about 0.6 liters. In one embodiment, for instance, the volume of the processing region can be from about 0.3 liters to about 0.6 liters. For larger substrates, the volume may need to grow in proportion with the substrate area.

The processing region can include a substrate staging area. The substrate staging area can include a substrate pedestal for holding the substrate. The outlet of the processing region can be located on the periphery of the substrate staging area or can be located remote from the substrate staging area. When remote from the substrate staging area, in one embodiment, the processing region defines a linear pathway from the substrate staging area to the outlet. For example, the processing region can include a slit-like pathway from the substrate staging area to the outlet. The slit, for instance, may have a ring-like shape and may extend downwardly from the substrate staging area. Alternatively, the processing region can include a slit-like pathway or a channel-like pathway that extends horizontally from the processing region. For example, the processing region may extend in a direction generally parallel with a substrate contained on a substrate pedestal. By having a substantially linear pathway, there is less likelihood that fluid flow through the processing region will become turbulent or otherwise disruptive. For instance, in one embodiment, the processing region can be designed so that fluid flow through the chamber is laminar.

In order to facilitate the flow of gases and vapors through the processing region, in one embodiment, the system can include a pumping device that pumps fluids from the chamber into an exhaust channel. The process chamber may be configured to operate at any suitable pressure. For instance, the process chamber may be configured to operate at a pressure anywhere below atmospheric pressure (about 760 Torr). For example, the process chamber may operate at a pressure of anywhere between about 600 Torr and about 0 Torr. In one embodiment, the process chamber may be configured to operate at sub-atmospheric pressures, such as from about 20 Torr to about 2 Torr.

One of the primary benefits of the above-described system is the ability to rapidly control pressures within the processing region of the process chamber. For instance, by including a conductance valve as described above, the system is capable of carrying out processes in which the pressures in the processing region can be rapidly varied while flowing chemical species into the processing region for interaction with a substrate contained in the processing region. For instance, in one embodiment, a process can be carried out in which the conductance of a chemical species through the processing region can be varied by changing the position of the conductance-limiting element. The processing region can alternate between a high pressure and a low pressure. The high pressure can be at least about 0.5 Torr greater than the low pressure. In fact, the high pressure can be ten times greater than the low pressure or several hundred times greater than the low pressure. In accordance with the present disclosure, the transition of the chamber pressure from the low pressure to the high pressure and from the high pressure to the low pressure can be carried out very rapidly. For instance, both transitions can occur sequentially at times less than about 500 ms, such as less than 350 ms, such as less than 250 ms, such as less than 100 ms.

More particularly, the transition of the chamber pressure from low pressure to high pressure can be less than about 500 ms, such as less than about 100 ms. Similarly, the transition of the chamber pressure from high pressure to low pressure can be less than about 250 ms, such as less than about 50 ms.

During processing, the processing region can be maintained at the low pressure and/or at the high pressure for any desired length of time. For instance, the processing region can be maintained at the high pressure and/or at the low pressure for a time of from about 100 ms to about 2 seconds, such as from about 500 ms to about 1 second, such as from about 20 ms to about 200 ms. The length of time that the processing region is maintained at the high pressure and/or at the low pressure, however, depends upon numerous factors, including the particular process being carried out.

The period of time the processing region is maintained at high pressure, the time of transition from high pressure to low pressure, and the period of time the processing region is maintained at low pressure, and the time of transition from low pressure to high pressure comprises one pressure cycle. In one embodiment, the processing region may undergo multiple pressure cycles while the chemical species is flowing into the processing region. In an alternative embodiment, different chemical species or different concentrations of unique chemical species may be introduced in the processing region during multiple pressure cycles. The chemical species can flow into the processing region at any suitable flow rate. For exemplary purposes, the flow rate may be from about 20 sccm to about 2000 sccm.

Using the conductance valve of the present disclosure in the above-described process provides various advantages and benefits. For instance, use of the conductance valve with a suitable sized evacuation system allows for very rapid pressure cycle times not previously achievable in sub-atmospheric process systems. Pressure cycle frequencies, for instance, can be from about 0.05 Hz to about 50 Hz, such as greater than about 2 Hz, such as greater than about 5 Hz, such as greater than about 10 Hz, such as greater than about 20 Hz.

In addition, pressure drops can occur very rapidly. The pressure within the processing region, for instance, can be reduced by at about 200 Torr in less than about 500 ms, such as less than about 250 ms.

In still another embodiment, the present disclosure is also directed to a method for calibrating a variable conductance valve as described above. The variable conductance valve, for instance, can include an oscillating or rotating conductance-limiting element in operative association with at least one actuator. The variable conductance valve can be calibrated by driving the actuator to a stop position while monitoring a drive current and an encoder position. When a slope of the drive current versus a position curve equals a predetermined value, the encoder is recorded and used to reset a zero position of the conductance valve. In one embodiment, the conductance valve can include more than one actuator, such as three actuators. In this embodiment, each actuator can independently undergo the calibration method described above.

Other features and aspects of the present disclosure are discussed in greater detail below.

### BRIEF DESCRIPTION OF THE DRAWINGS

A full and enabling disclosure of the present invention, including the best mode thereof, directed to one of ordinary skill in the art, is set forth more particularly in the remainder of the specification, which makes reference to the appended figures, in which:

FIG. 1 is a cross-sectional view of one embodiment of a process system made in accordance with the present disclosure;

FIG. 2 is a cross-sectional view with cut-away portions of the process chamber illustrated in FIG. 1 particularly showing one embodiment of a pre-exhaust region;

FIG. 3 is an isolated perspective view of one embodiment of a conductance valve that may be used in the process chamber illustrated in FIG. 1;

FIG. 4 is a perspective view with cut-away portions of one embodiment of a voice coil actuator that may be used to construct a conductance valve in accordance with the present disclosure;

FIGS. 5 through 9 are graphical representations of design simulations or experimental measurements regarding the properties of process chambers made in accordance with the present disclosure; and

FIG. 10 is a schematic view of one embodiment of a diagram for feeding fluids into a processing chamber in accordance with the present disclosure.

FIG. 11 shows a schematic view of a wafer process module that employs the concepts developed in this disclosure to perform a step by step process cycle using two reactant gas mixtures, Gas A and Gas B. The process module uses a shower head for gas distribution of Gas A and direct chamber injection for Gas B. The diagram also shows a showerhead by pass valve to improve the gas exchange rate in the process chamber.

FIG. 12 shows the results of a simulation of the wafer process module of FIG. 11 where the process chamber pressure and showerhead pressures are displayed in the upper plot and the corresponding valve timing sequence is shown in the lower plot. Values used in this simulation are based on the model shown in FIG. 1, except with the upper chamber replaced with a conventional gas showerhead.

Repeat use of reference characters in the present specification and drawings is intended to represent same or analogous features or elements of the invention.

### DETAILED DESCRIPTION

It is to be understood by one of ordinary skill in the art that the present discussion is a description of exemplary embodiments only, and is not intended as limiting the broader aspects of the present invention which broader aspects are embodied in the exemplary construction.

In general, the present disclosure is directed to a system for processing substrates, such as semiconductor wafers. The system includes a process chamber configured to hold substrates in a processing region and a conductance valve that allows for the pressure inside the processing region to be rapidly varied as desired.

In the past, some of those skilled in the art have suggested that pressure variations within a processing chamber during semiconductor wafer processing should be avoided. Thus, it is been proposed in the past to maintain a constant pressure within the processing chamber during wafer processing in order to improve process control and reduce unwanted particle transport to the wafer surface. For instance, PCT Publication No. WO 2004/083485 to Liu discloses a system and process for atomic layer deposition in which the reactor chamber is maintained at a nominally constant pressure.

The present inventors have discovered, however, that various advantages and benefits may be obtained if the pressure of the processing chamber can be varied rapidly in a controlled manner during processing. For example, process chambers made according to the present disclosure can be placed in communication with a conductance valve that provides well-controlled and rapid pressure changes in the processing region of the process chamber. Further, in addition to the use of the conductance valve, in one embodiment, a process chamber made in accordance with the present disclosure may be constructed so as to have a minimum volume of pre-exhaust in between the processing region and the conductance valve. Being able to rapidly change the pressure in the processing region combined with a minimum volume of pre-exhaust region has been found to prevent the recirculation of unwanted particles. In fact, the pressure variations as will be described in greater detail below can improve the properties of the structures being formed on the substrate and/or the condition of the substrate surface.

Those skilled in the art have attempted in the past to control the flow of exhaust through a semiconductor substrate process chamber. For instance, U.S. Pat. No. 6,777,352 to Tepman, which is incorporated herein by reference, discloses a variable flow deposition apparatus. The system of the present disclosure, however, includes a conductance valve that is designed specifically to change its state from fully open, maximum conductance, to fully or nearly fully closed, minimum conductance, or from fully closed to fully open much faster than any previous valve controlling an exhaust stream having a relatively high cross-sectional area for processing substrates sub-atmospherically and acts on a minimally sized process region and therefore can adjust process pressures in a processing region in a much more rapid fashion than done in the past. For example, the system of the present disclosure includes a conductance valve that can be designed to move between fixed settings of a conductance-limiting element, such as fully open or fully closed in less than 10 ms with a recommended service after 200,000,000 cycles. This level of performance provides a unique capability not currently met by commercially available valves. As will be described in greater detail below, the system and process of the present disclosure also provides various other benefits and advantages.

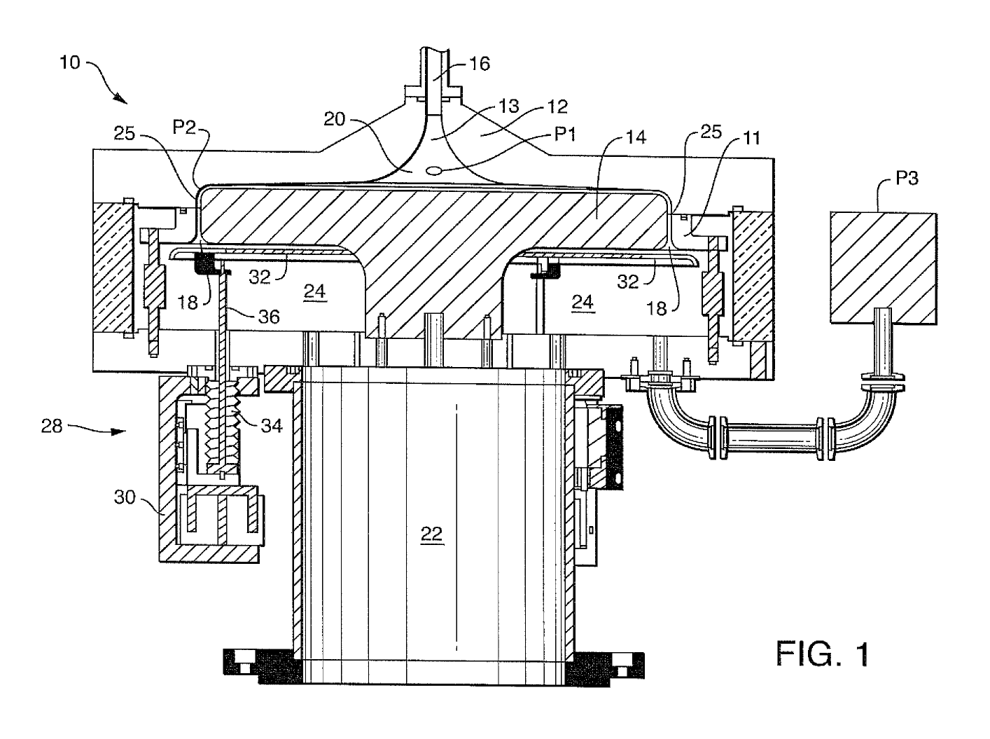

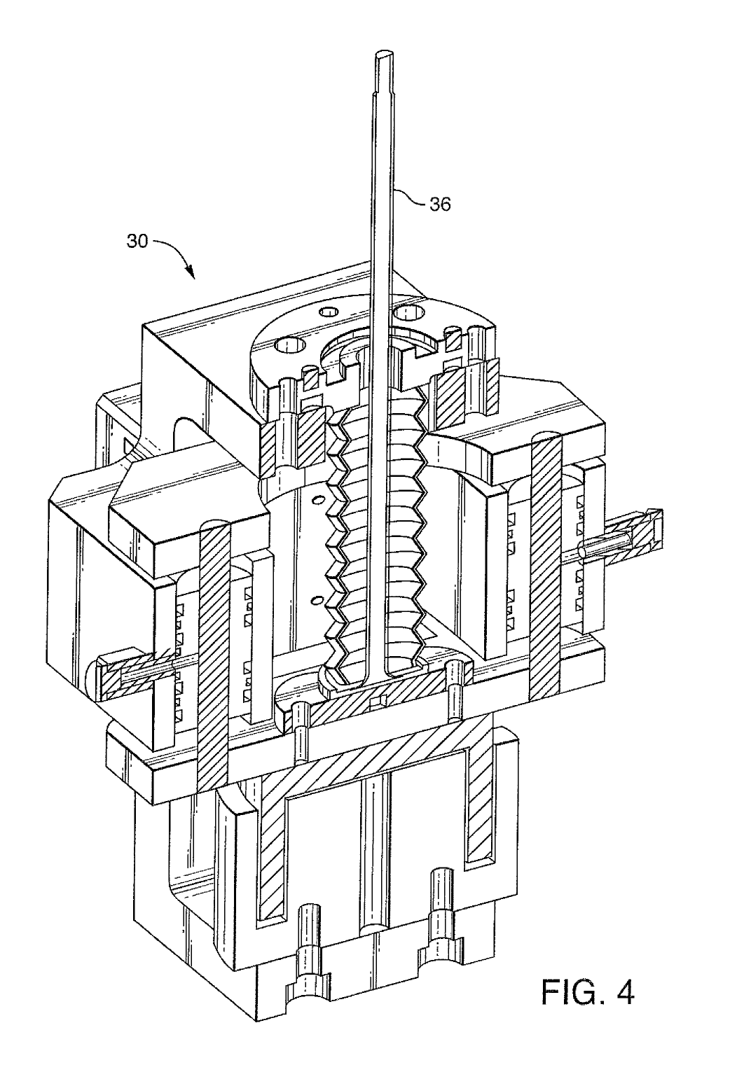

Referring to FIGS. 1 through 4, one embodiment of a processing system 10 generally made in accordance with the present disclosure is shown. As illustrated in FIG. 1, the processing system 10 includes a process chamber 12 defining a processing region 13 configured to receive a substrate, such as a semiconductor wafer for conducting various processes. The processing region 13, for instance, includes a substrate pedestal 14 that is designed to hold the substrate within the processing region.

The process chamber 12 can be made from various materials depending upon the particular application and the process being conducted within the chamber. For instance, the chamber can be made from metal, ceramics, or a mixture of both including but not limited to aluminum or stainless steel, and aluminum oxide or aluminum nitride. The processing system 10, for instance, can include a “cold wall” system in which the process chamber includes interior walls made from a heat conductive material, such as aluminum. Alternatively, the processing system can include a “hot wall” process chamber that includes interior walls made from a conductive material such as aluminum or non-conductive material, such as quartz. Alternatively, the interior walls of the processing region can be coated with various coatings, such as Yttria, aluminum nitride, or aluminum oxide, that are non-reactive to processes to be performed in the process chamber.

As will be described in greater detail below, the processing system 10 can be designed to carry out many different processes. In some processes, the substrate contained within the processing chamber 12 can be heated. Thus, although optional, in some embodiments the processing system 10 may include a device in communication with the processing chamber 12 for controlling the temperature of the substrate contained upon a substrate pedestal. In the embodiment illustrated in FIG. 1, for instance, the processing system 10 includes a heated substrate pedestal 14 that is positioned below a substrate contained within the processing region. The heated substrate pedestal 14 can heat substrates within the processing region using different techniques. The substrate pedestal, for instance, can include a heating element, such as an electrical resistance heater or an induction heater for heating the substrate.

Instead of or in addition to using a heated susceptor 14, it should be understood that the processing system 10 may include various other heating devices. For instance, in an alternative embodiment, the heating device may comprise a plurality of lamps, such as tungsten-halogen lamps, arc lamps, lasers, or a mixture thereof. The lamps, for instance, can be positioned above the substrate, may be positioned below the substrate, or may be positioned above and below the substrate. Further, if desired, the lamps can be surrounded by a reflector or set of reflectors for directing thermal energy being emitted by the lamps onto the substrate at particular locations. When incorporated into the processing system 10, lamps can provide very high heating rates. The use of lamps, for instance, can create a rapid thermal processing system that provides instantaneous energy, typically requiring a very short and well-controlled start-up period. The flow of energy from lamps can also be abruptly stopped at any time. In one embodiment, heat lamps can be used in conjunction with the temperature controlled substrate pedestal 14. The temperature controlled pedestal 14, for instance, can be used to control the temperature of the substrate over a surface of the substrate, while the lamps can be used to heat the substrate at particular locations or to rapidly heat the substrate globally at a particular time or times during a process being carried out in the process chamber.

When the temperature of substrates is being controlled in the process chamber, in some embodiments, it may be desirable to monitor the temperature of the substrates. In this regard, the processing system 10 can include one or more temperature sensing devices. For instance, in one embodiment, the processing system 10 can include one or more radiation sensing devices. Radiation sensing devices sense the amount of radiation being emitted by the substrate at a particular wavelength. This information can then be used to determine the temperature of the substrate without contacting the substrate. In one embodiment, for instance, the radiation sensing device may comprise a pyrometer. Pyrometers include, for instance, a light pipe that is configured to receive radiation being emitted by the substrate. The light pipe, which may comprise, for instance, an optical fiber, may be in communication with a light detector. The light detector may generate a usable voltage signal for determining the temperature of the substrate.

As described above, the processing system 10 can include one or more temperature sensing devices if desired. The temperature of the substrate, for instance, may be monitored at different locations on the substrate. Knowing the temperature of the substrate at different locations can then be used to control the amount of heat being applied to the substrate for carefully heating the substrate according to a particular temperature regime.

For example, in one embodiment, the processing system 10 can further include a controller, such as a microprocessor or programmable logic unit. The controller can be placed in communication with the one or more temperature sensing devices and in communication with the heating device, such as the temperature controlled pedestal 14. The controller can receive information from the temperature sensing devices and, in turn, control the amount of heat being emitted by the heating device for heating the substrate. The controller, for instance, can control the heating device in an open loop fashion or in a closed loop fashion.

In one embodiment, the controller can also be used to automatically control other elements within the system. For instance, the controller can also be used to control the flow rate of fluids entering the chamber 12, such as gases and vapors. In addition, in one embodiment, the substrate pedestal contained within the processing chamber may be configured to rotate the substrate during processing. Rotating the substrate may promote greater temperature uniformity and may promote enhanced contact between the substrate and any fluids being circulated through the processing region resulting in greater process uniformity. The controller, in one embodiment, can be used to control the rate at which the substrate is rotated within the chamber.

In accordance with the present disclosure, the processing region 13 further includes an inlet 16 and an outlet 18. The inlet 16 and the outlet 18 are for circulating one or more fluids through the processing region. For instance, a precursor fluid, such as a gas, a mixture of gases, a liquid vapor, or a mixture of liquid vapors and/or gases can be introduced into the processing region 13 for interacting with a surface of a substrate contained within the chamber. For example, any suitable chemical species may be introduced into the processing region 13 through the inlet 16 in order to form a film or coating on the surface of the substrate.

The inlet 16 can comprise any structure capable of delivering a fluid into the chamber. As shown in FIG. 1, for instance, the inlet 16 can simply comprise a conically shaped passageway. In an alternative embodiment, the inlet 16 may comprise a shower head-like injector. In yet an alternative embodiment, the inlet 16 and outlet 18 may be arranged such that they are oriented in the same horizontal plane as to form a cross-flow configuration with regard to the surface of the substrate. As will be described in greater detail below, the inlet 16 may also be in communication with any suitable fluid delivery device that is capable of pulsing chemical species into the processing region.

In still another embodiment, the inlet 16 may be in communication with a plasma source, such as an inductively coupled plasma source, for generating and providing ions into the chamber. Plasma sources may be used in conjunction with the inlet 16, for instance, during plasma-enhanced deposition or during various etching processes or during surface conditioning or cleaning processes.

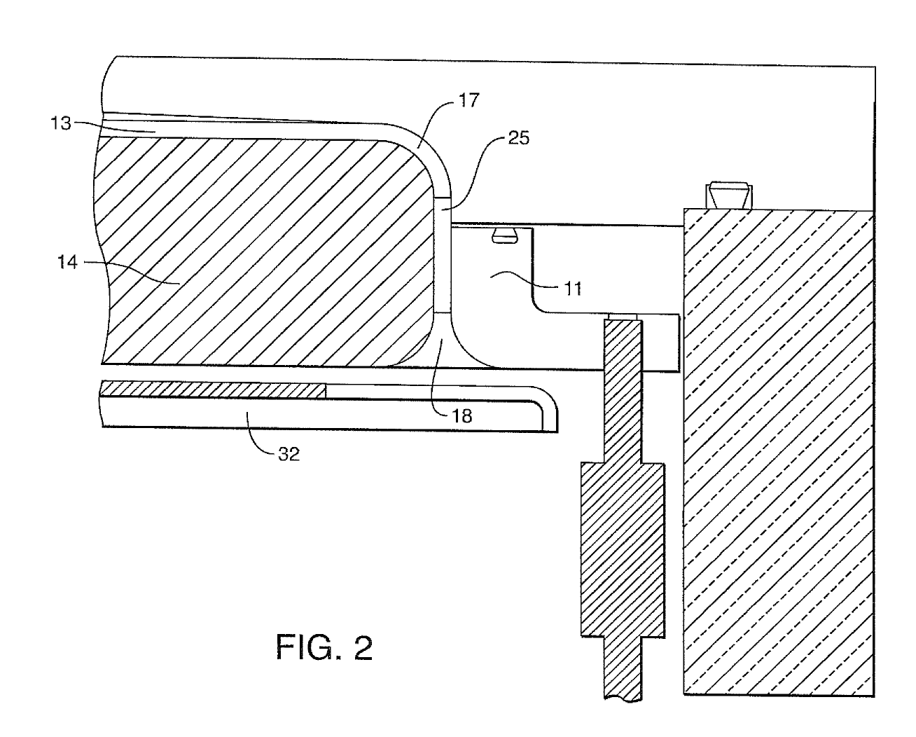

As fluids, such as gases and vapors, are fed through the processing region 13, the fluid contacts the substrate and particularly the top surface of the substrate prior to exiting the chamber 12. The fluids exit the processing region through a flow management region 25. As shown in the embodiment illustrates in FIGS. 1 and 2, in this embodiment, the flow management region 25 has a ring-like shape such that once fluids contact the substrate, the fluids can exit the processing region 13 in any suitable direction. It should be understood, however, that the flow management region 25 can have any suitable shape. As will be described in greater detail below, the flow management region is designed to minimize gas recirculation and have minimum volume so as to not substantially increase the time it takes to evacuate the processing region to a desired pressure. As shown in FIG. 1, the flow management region 25 terminates at an outlet 18.

From the outlet 18, the fluids are then fed into a lower part of the chamber 24 and into an exhaust channel 22. As shown in FIG. 1 and FIG. 2, in this embodiment, the processing region 13 includes a substrate staging area 20 that feeds into a region 17 where the direction of the fluid is changed and fed into the flow management region 25. The flow management region 25 surrounds the substrate pedestal in the substrate staging area 20 and is formed between a wall of the substrate pedestal 14 and a sidewall 11 of the process chamber. The exhaust channel 22 can be placed in communication with a pumping device that is configured to pump gases and/or vapors from the processing region 13 and through the flow management region 25. The pumping device, for instance, cannot only be used to assist in flowing fluids through the system but can also be used to lower the pressures within the processing region 13. For instance, in many applications, processes can be carried out in the processing region 13 at very low pressures, such as less than about 10 Torr. It should be understood, however, that the process chamber of the present disclosure may also operate at atmospheric pressure or anywhere between atmospheric pressure and near vacuum conditions. For instance, the process chamber may operate at a pressure of from about 760 Torr to about 2 Torr or less. When operating below atmospheric pressures, the processing region may be at a pressure of from about 600 Torr to near zero Torr.

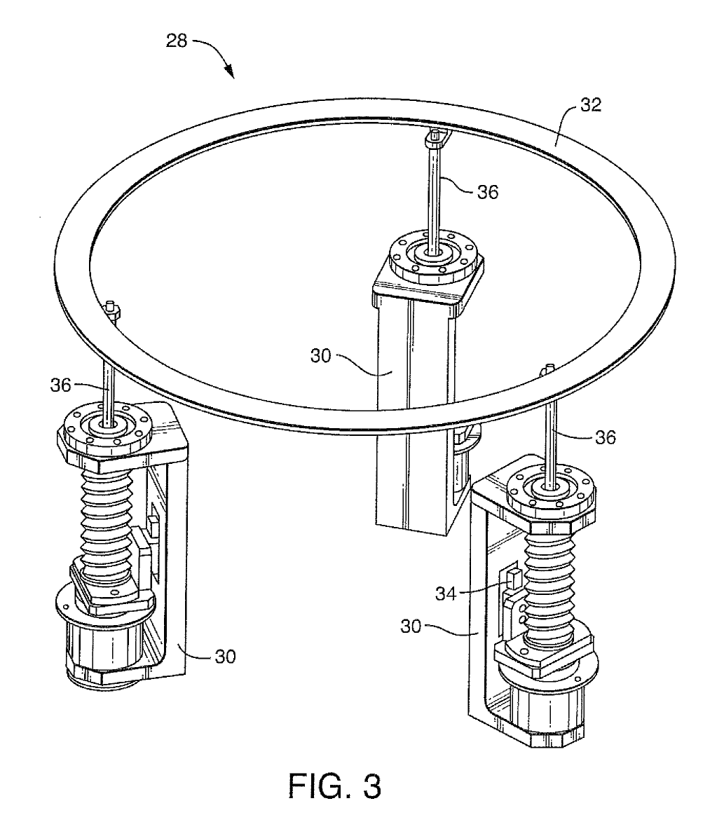

As shown in FIG. 1 and in accordance with the present disclosure, positioned at the outlet 18 is a conductance valve 28. As shown in FIG. 3, the conductance valve 28 includes one or more voice coil actuators 30 that are in operative associate with a conductance-limiting element 32 via an air bearing 34. Specifically, the voice coil actuators 30 are connected to the conductance-limiting element 32 by a linking arm 36. As shown, the conductance-limiting element is flat and horizontal but in other embodiments, it can take a different shape and orientation such that it cooperates with the flow management region 25 to minimize conductance when in the closed position. For example, the conductance-limiting element 32 may form an outlet with a conductance path to minimize gas conductance when the conductance-limiting element is in the closed position.

As described above, the flow management region 25 has a ring-like shape. Although optional, the outlet 18 can flare outwardly, and have a conical shape.

In order to control pressures within the processing region 13, the conductance-limiting element 32 of the conductance valve 28 is positioned opposite the outlet 18. During processing, the conductance-limiting element 38 can be moved into and out of engagement with the outlet. For instance, the conductance-limiting element 32 can be oscillated or rotated into and out of engagement with the outlet 18 by the voice coil actuators 30. In this manner, pressure within the processing region 13 can be rapidly adjusted between a high pressure and a low pressure by moving the conductance-limiting element closer to and away from the outlet.

In one embodiment, the conductance-limiting element 32 can form a seal against the outlet 18 of the flow management region 25 when the conductance-limiting element 32 is in a closed position. If necessary, a seal such as an o-ring can be placed surrounding the outlet 18 in order to ensure that a proper seal is formed.

Alternatively, the conductance-limiting element 32 of the conductance valve 28 may form a non-sealing engagement with the outlet 18. In this embodiment, for instance, the conductance-limiting element may still move between an open position and a closed position. In the closed position, however, a very small gap may still remain between the outlet 18 and the top surface of the conductance-limiting element 32. Of particular advantage, the present inventors have discovered that the voice coil actuators 30 are well adapted for precisely controlling the position of the conductance-limiting element 32. Thus, the voice coil actuator 30 is capable of placing the top surface of the conductance-limiting element repeatable within microns of the outlet 18 of the processing region 13. For example, in one embodiment, when in a closed position, the gap formed between the conductance-limiting element 32 and the pre-exhaust region 18 can be less than about 100 microns, such as from about 30 microns to about 10 microns.

When in the open position, on the other hand, the conductance-limiting element 32 may form a gap with the flow management region 25 that is greater than about 0.5 mm, such as greater than about 1 mm, such as greater than about 2 mm. For instance, in one embodiment, the gap formed between the conductance-limiting element 32 and the outlet 18 may be from about 1 mm to about 5 mm when in the open position.

As described above, the high tolerances achieved with placement of the conductance-limiting element 32 in the closed position are controlled by the voice coil actuators 30. Voice coil actuators are electromagnetic devices that produce accurately controllable forces over a limited stroke with a single coil. Voice coil actuators as used in the present disclosure are capable of extremely high accelerations and great positioning accuracy.

In one embodiment, in order to better control the position of the conductance-limiting element 32, the voice coil actuators 30 may be in communication with an encoder, such as an optical encoder. For example, the encoder can include, for instance, a laser diode that is capable of sensing a pattern indicating the position of the conductance-limiting element. The encoder can be in communication with each of the voice coil actuators 30 in order to ensure that the conductance-limiting element 18 is in the proper position. For example, in one embodiment, depending upon the process, the encoder can be calibrated so that the conductance-limiting element oscillates between desired fixed positions. After being calibrated, the encoder can be used to ensure that the conductance-limiting element maintains any desired position within its range of travel during processing.

For some types of processes, the conditions of the process may affect the conductance of the value. An example of such processes might include etch or ALD processes in which by products may coat the areas that define the valve conductance of the valve. The use of the voice coil actuator provides a convenient means to periodically check the calibration and recalibrate the encoder position to assure the minimal conductance value stays within a specified tolerance. The current to the voice coil is proportional to the force applied to the valve. If the valve is fully closed to a fixed force level, this assures the valve is seated at the same closed position of the previous calibration. The encoder position is reset and the valve is then returned to operation. This procedure could be performed as often as between each product wafer cycle if desired. The procedure could be performed during wafer exchange so if would have no impact on throughput of the system.

The pressure response of the processing region 13 to a variation in input fluid flow is determined by its volume and exhaust region conductance. The conductance valve 28 as shown in FIGS. 1 through 4 has been found to significantly increase the pressure response significantly both for the transition from low to high pressure and from the transition of high to low pressure as will be shown in more detail below. Thus, using the conductance valve 28, the pressure in the processing region 13 can be varied between a low pressure and a high pressure or from a high pressure to a low pressure at extremely fast response times. Further, the pressure transition within the processing region 13 can be on a factor of 10 or larger. For example, the conductance valve 28 when used with a processing chamber can transition from a pressure of less than a Torr to pressure of greater than 1 Torr at times recorded in tens of milliseconds. The pressure difference when transitioning from high pressure to low pressure or from low pressure to high pressure, for instance, can be as little as 0.5 Torr or as much as 200 Torr or greater. Similarly, the processing region 13 can transition from the high pressure to the low pressure when desired also as quickly as tens of milliseconds.

In addition to using the conductance valve 28, control over the process can also be optimized by minimizing the volume of the processing region 13. As used herein, the processing region 13 is defined by the processing space that is directly affected by the conductance valve 28. For instance, as shown in FIG. 1, the processing region 13 extends from the outlet 18 to the inlet 16. According to the present disclosure, the volume of the processing region 13 for a 300 mm diameter wafer type of substrate can generally be less than 1 liter, such as less than about 0.6 liters, such as less than about 0.5 liters. For instance, in one embodiment, the volume of the processing region can be from about 0.3 liters to about 0.6 liters.

As shown in FIG. 1, the processing region 13 generally includes the substrate staging area 20 in addition to the flow management region 25. In one embodiment, the processing region 13 can be designed so that fluid flow through the processing region is designed to avoid any fluid recirculation loops that may cause longer residence times and/or contamination to form during the process. Controlling the shape and volume of the processing region 13 can also provide a marked improvement in pressure response.

For instance, in one embodiment, the outlet 18 of the processing region 13 can be positioned so that fluid flow through the chamber does not include any turbulent paths. For instance, in one embodiment, the outlet 18 can be positioned directly on the outer periphery of the substrate staging area 20. In the embodiment shown in FIG. 1, the outlet 18 is positioned at the end of the ring-like channel or slit that comprises the flow management region 25. As shown, the channel generally provides a linear pathway such that once a fluid exits the wafer staging area, the fluid flow is generally linear in a straight line. Specifically, in the embodiment illustrated, once a fluid contacts the surface of a substrate in the processing chamber, the fluid flows in a linear and horizontal outward direction over the substrate and then downward through the flow management region 25.

Instead of extending in a downward direction, it should be understood that the outlet 18 can be positioned at any direction that is linear from the wafer staging area 20. For instance, in an alternative embodiment, the outlet 18 may be separated from the substrate staging area 20 by a linear pathway that extends only in a horizontal direction. For instance, the outlet 18 can be at a location that is generally parallel with a substrate contained within the chamber.

Any channels or pathways that extend from the substrate staging area 20 should have a relatively small volume. For instance, the volume of the flow management region 25 can be less than about 0.5 liters, such as less than about 0.3 liters, such as less than about 0.1 liter. For example, in one embodiment for a 300 mm diameter semiconductor wafer type substrate, the volume of the flow management region 25 can be from about 0.1 liters to about 0.03 liters. In one particular embodiment, the volume of the flow management region 25 can be about 0.07 liters which thus only represents a small fraction of the total volume of the processing region. The volume of the flow management region 25, however, may be proportional to the size of the treated substrate.

In the figures illustrated, as described above, the slit or channel of the flow management region 25 has a ring-like shape. It should be understood that the channel can have any suitable cross-sectional shape. For instance, the channel can have a circular or rectangular pathway leading from the substrate staging area. Likewise, the conductance-limiting element 32 can have any suitable shape depending upon the shape of the outlet. In the embodiments illustrated in FIGS. 1 through 4, for instance, the conductance-limiting element has a ring-like shape in order to cover the outlet. In other embodiments, however, the conductance-limiting element may have a circular shape, a rectangular shape, or any other suitable configuration. Further, in addition to oscillating towards and away from the outlet, the conductance-limiting element can also be configured to rotate in between open and closed positions.

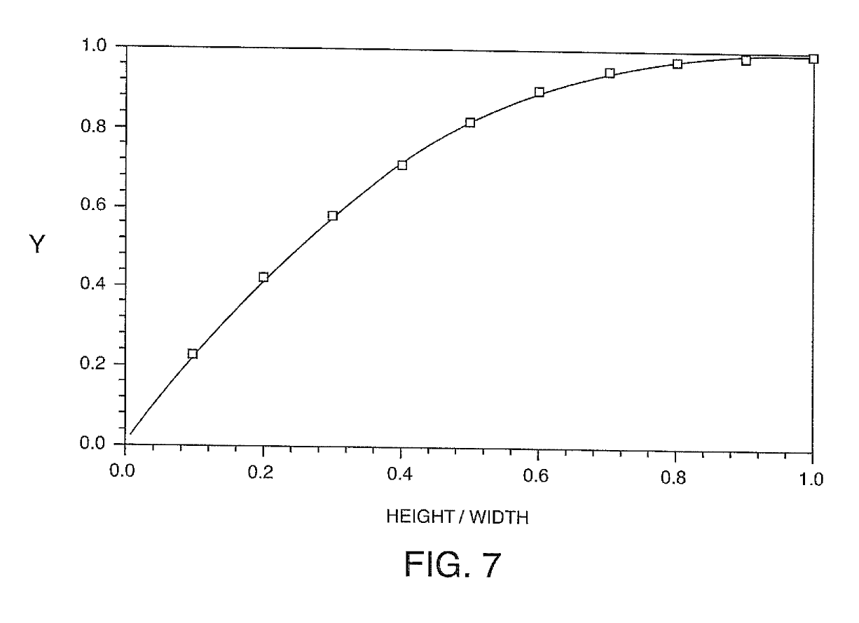

In order to exemplify other embodiments where the channel of the flow management region 25 is not in the shape of a slit, FIG. 7 relates the cross-sectional area of a slit back to and equivalent to cross-sectional area of a circular outlet with the same conductance. More particularly, when the conductance valve of the present disclosure is in an open position that is from about 1 mm to about 2 mm spaced from the outlet 18, such as about 1.5 mm away from the outlet, the condition of the gas flow is typically in the viscous flow regime. Under these conditions, gas flow is dictated mostly by bulk conditions away from the surrounding surfaces. For viscous flow as described above, it is possible to directly relate the cross-sectional area of the slit to the equivalent cross-sectional area of a circular outlet according to the following formula:

For viscous flow: equivalent circular area=(0.88Y)^{1/2}(Area rectangle)

As shown in FIG. 7, the relationship of circular cross-sectional shape to a rectangular cross-sectional shape depends upon the aspect ratio of the slit. The aspect ratio of the slit illustrated in FIG. 1, for instance, can be from about 0.08 to about 0.02, such as about 0.05. At an aspect ratio of 0.05, for instance, the equivalent circular cross-sectional area is normally about four percent of the size of a rectangular cross-sectional area. Thus, in some embodiments, there may be advantages and benefits to having a channel having a circular shape as opposed to a slit-like shape that extends from the substrate staging area.

When the conductance valve is in the closed position in a non-sealing arrangement, flow through the channel when in the shape of a slit is typically under molecular flow conditions (conductance-limiting element spaced less than 50 microns such as about 25 microns from the second end of the pre-exhaust region). Under these conditions, gas flow interacts strongly with the surfaces that contain it. The relationship between an equivalent circular cross-section and a rectangular cross-section cannot be directly related as the conductance also depends on the length of the opening. But in any case, it can be estimated that a slit ending in a narrow and wide slot of aspect ratio close to 0.05 is approximately 60 percent more efficient than an equivalent circular outlet.

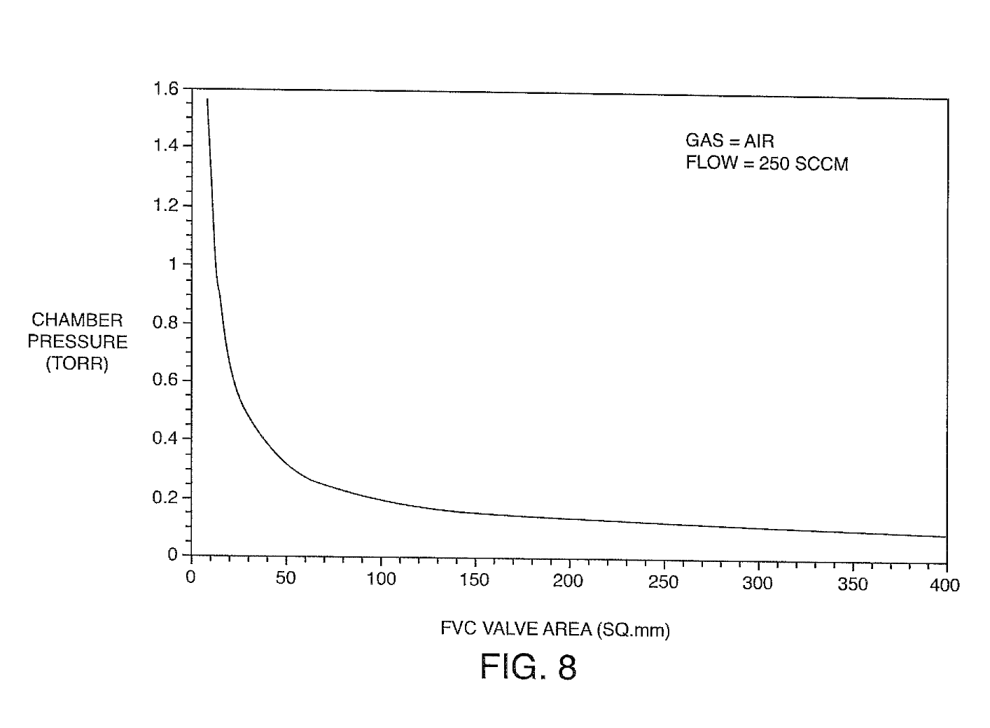

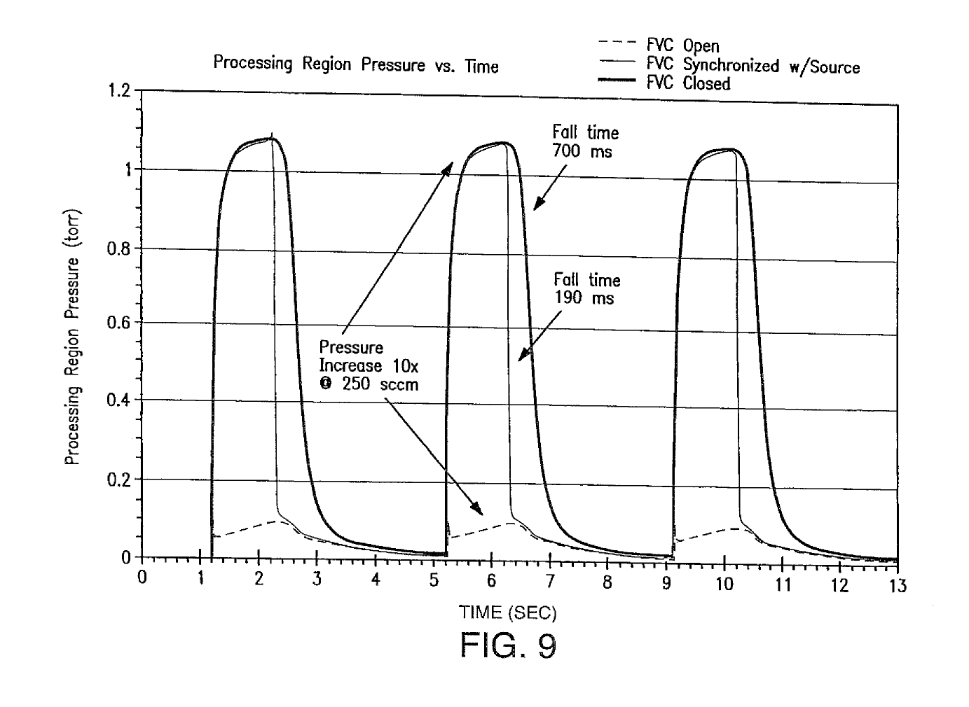

The implementation of the conductance valve as a slit can provide many benefits and advantages. Use of a slit-like shape as the channel, however, may require good control and repeatability of the motion of the conductance-limiting element of the conductance valve to provide stability during multiple processes. As shown in FIG. 8, for instance, an increase in process chamber pressure becomes increasingly more sensitive to changes in outlet cross-sectional area as a larger increase is desired. More particularly, the graph illustrated in FIG. 8 represents a simulated pressure increase a constant flow of 250 sccm plotted versus corresponding conductance valve equivalent circular area. As described above, the conductance valve of the present disclosure is capable of very rapidly transitioning pressure within the processing chamber from low to high pressure and from high to low pressure. Referring to FIG. 9, for instance, simulated test results are illustrated.

In particular, three curves are plotted in FIG. 9 to demonstrate the benefits of the conductance valve for creating not only a larger increase in pressure to a given flow but to also dramatically reduce the transition time from high to low pressure and from low to high pressure. For each curve, the gas flow into the processing region was pulsed for one second from 0 to 250 sccm. The first curve or bottom curve illustrates the pressure response in the processing region with the conductance valve in its open position forming a gap of 1.5 mm in between the conductance-limiting element and the outlet. The simulated pressure response data shown in FIG. 9 were produced based on a chamber model as shown in FIG. 1. As illustrated, when the conductance valve was left in its open position, the pressure of the processing region only increased to about 0.1 Torr.

A second curve illustrated in the graph indicates the pressure response when the conductance valve is held in a closed, non-sealing position. Particularly, the data was generated based on the conductance-limiting element forming a gap of 25 microns with the outlet. As shown, the pressure in the processing region varied from almost 0 to about 1.1 Torr. However, as shown in FIG. 9, when the valve was in the closed position, it takes about 700 ms for the pressure to transition from high to low.

In the final curve, the conductance valve was synchronized with the gas pulse. In particular, the conductance valve was moved to the open position at the end of the gas pulse. As shown, in this manner, the transition time from high pressure to low pressure is drastically reduced. For instance, the transition time from high pressure to low pressure was less than 200 ms.

In the embodiment illustrated in FIG. 9, gas was pulsed into the chamber. When pulsing the gas, as described above, the conductance valve can be synchronized with the beginning and the ending of the pulse. For instance, the valve can be closed during the beginning of the pulse and opened at the end of the pulse. In this manner, the conductance valve creates pressure variations within the chamber that can improve by orders of magnitude the exchange of gas ambient required for processes to occur. If the chamber were maintained a constant pressure, on the other hand, purging of the gas within the chamber would decay only exponentially with a time constant equal to the residence time.

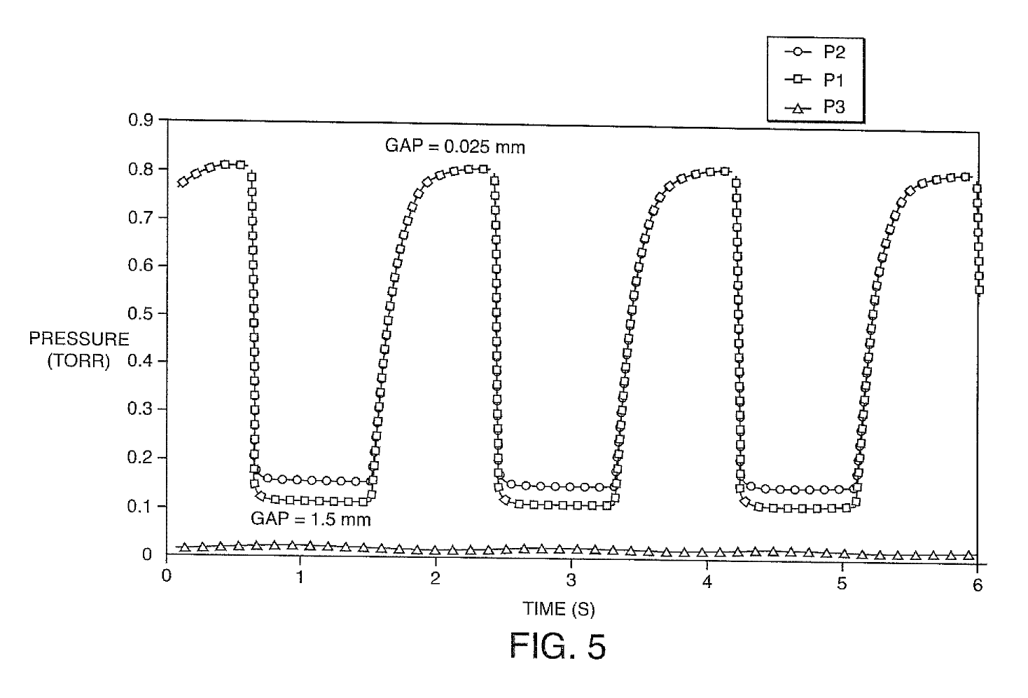

It should be understood, however, that the conductance valve and processing system of the present disclosure can also be used in processes in which gas flow is maintained at a constant rate. For instance, FIG. 5 illustrates experimental pressure measurements taken using a processing system similar to that shown in FIG. 1. In FIG. 5, gas was introduced into the processing region at a constant flow of 250 sccm. Pressure was monitored at the center of the processing region (P2), at the edge of the processing region (P1) and downstream from the conductance valve (P3) (see FIG. 1).

During gas flow, the conductance valve oscillated between an open and a closed position. In the open position, the gap between the conductance-limiting element of the conductance valve and the outlet was 1.5 mm. In the closed position, on the other hand, the gap was only 25 microns. By oscillating the conductance-limiting element of the conductance valve, pressure variations within the processing region varied from about 0.1 Torr to greater than 0.8 Torr. As shown, pressure transitions occurred extremely fast. For instance, the transition from high pressure to low pressure was approximately 60 ms. These rapid pressure transitions in the processing region are not reflected in the pressure of the process chamber region downstream of the conductance valve as evidenced by the nearly constant readings of the P3 signal shown in FIG. 5. The constant low pressure of the region downstream of the conductance valve prevents backflow of exhausted process fluids and byproducts from contaminating the processing region.

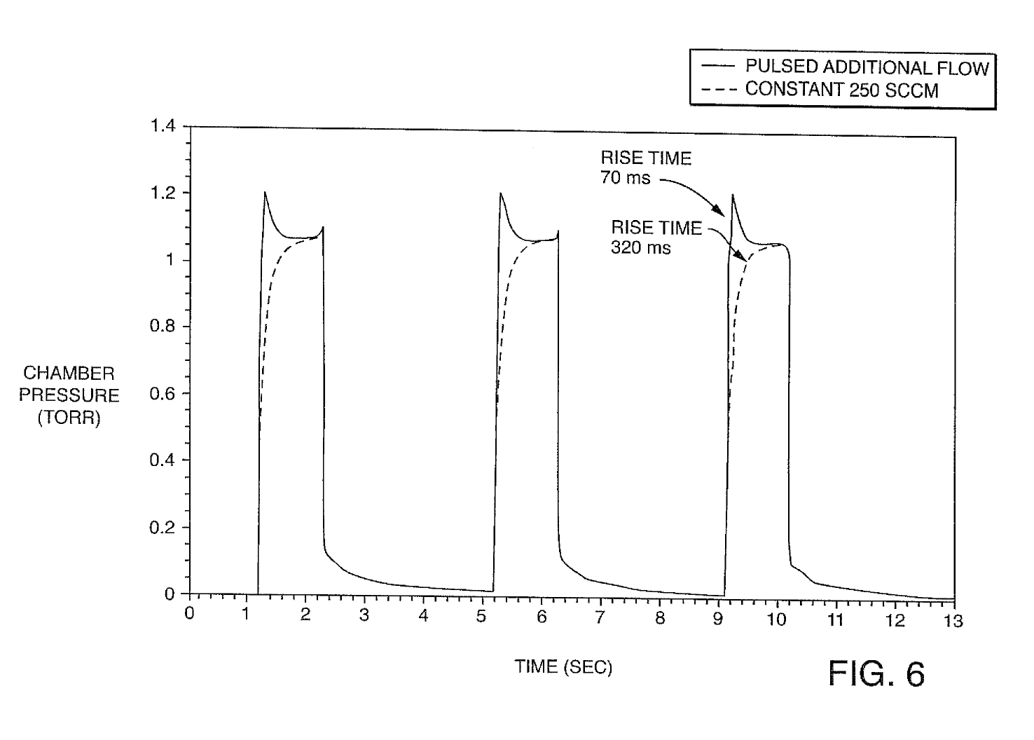

Depending upon the particular application, it may also be desirable to further increase the pressure response times when transition from low to high pressure. For example, in one embodiment, additional gas flow can be injected into the processing chamber synchronized with the rise time of a pressure pulse. Because of the effectiveness of the conduction valve, of particular advantage, only a small amount of fluid will have a large affect on the pressure transition time. For example, FIG. 6 illustrates simulated results indicating the increase in the rise time from low pressure to high pressure at constant gas flow in comparison to pulsed additional flow. More particularly, the pulsed additional flow was equivalent to four percent of the chamber of volume. As shown, the pulsed additional flow reduced the transition time from 320 ms to only 70 ms.

Various configurations can be used to provide the pulsed additional flow as shown in FIG. 6.

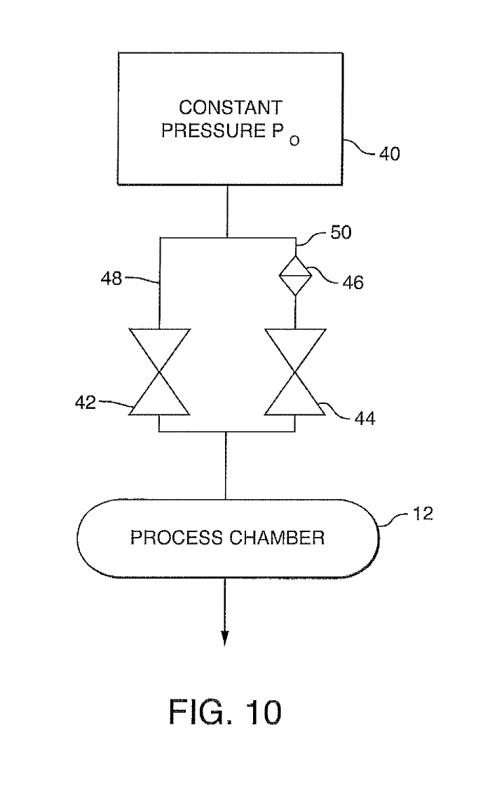

For example, one embodiment of a fluid supply configuration for the process chamber 12 is illustrated in FIG. 10. As shown, fluid can be supplied from a constant pressure source 40 into two parallel supply lines 48 and 50. The first supply line 48 includes a first valve 42 that controls fluid flow into the process chamber 12. The second supply line 50, on the other hand, includes a second valve 44 in conjunction with a flow restricting device 46 which can be, for instance, a needle valve, an adjustable orifice, and the like. The flow-restricting device is configured to reduce the flow of the fluid through the supply line 50. During processing, fluid pressure and the flow-restricting device can be adjusted to give the desired high pressure in the processing region during steady state with the conductance valve located in the processing system closed. The pulse shape can then be quickly optimized during cycling by adjusting the timing of the additional flow provided by flow through the unrestricted valve 42.

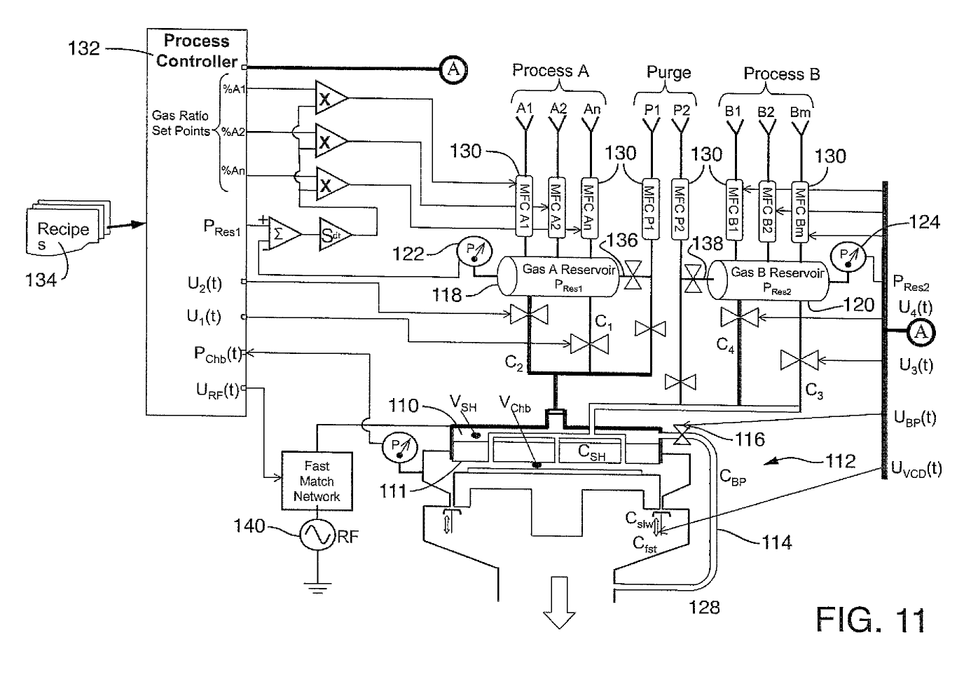

A schematic diagram of a process module showing elements for control of the gas flow pressure control, gas distribution combined with plasma processing capability is shown in FIG. 11. The schematic of the chamber module 112 is similar to that already describe where the chamber process module volume is small to facilitate rapid gas exchange. An added feature, shows a top portion that provides feed through to a gas or fluid showerhead 110. The showerhead has a small gas volume or plenum volume separated by a plate 111 with multiple holes to uniformly distribute the gas over the wafer surface. A pressure difference between the showerhead 110 and the chamber 112 will exist to provide uniform gas distribution. The showerhead 110 is supplied with process Gas A as shown in FIG. 11. A second gas or fluid, shown as Gas B is provided to the process module through a direct line into the process module and bypasses the showerhead distribution plate 111.

The plenum volume of the showerhead 110 is connected to the vacuum exhaust through a high conductance vent line 114 and fast acting valve 116. The opening and closing of the showerhead vent line 114 can be synchronized with the variable conductance valve 128 for the process module to effect rapid gas change in the process module.

Gas A and gas B are supplied from separate reservoirs 118 and 120 of pre-mixed gases. The pressure of the reservoirs is held at a constant pressure. The pressure of the reservoir is monitored by manometers 122 and 124 or other suitable pressure sensor. The flow of gas to the reservoirs is controlled by a series of mass flow controllers 130. The input to these controllers 130 is controlled by the controller 132. The process recipe 134 provides the correct ratio of gases. The output from the pressure sensors 122 and 124 is compared with the set point pressure P_{Res1,2}, and the difference signal is integrated over time. The resulting signal multiplies the fixed gas ratio values. The resultant signal controls the mass flow controllers 130 to supply the gas to the reservoirs maintains the reservoirs at a constant pressure within the time domain limits of the close loop control system. This is shown for a system with two gases, but could be generalize to any number of gases.

The connections between the process module 112 and gas reservoirs 118 and 120 are each made through two paths, one with a high conductance C_{2,4} and the other with a low conductance C_{1,3} to enable rapid filling of the process module as previously described. Purge gas lines 136 and 138 are provided to purge the gas lines and reservoir. The amount of gas delivered to the process chamber 112 in terms of flow and pressure during each cycle is thus controlled accurately and reproducibly for precise process control through the reservoir pressure and timing of the valve opening and closings. The overall process is controlled by a system controller 132 to perform a prescribed process recipe consisting of highly repeatable process cycles.

This process module concept includes an RF power supply 140 connected to a source antenna in the process module to create a plasma as required for the process. The sequencing of the RF power is controlled by the process controller 132.

For the purpose of illustration, a cyclic process sequence is carried out with the process module described in FIG. 11. The process requires the following process steps all performed in a short time sequence:

1. Flow gas mixture A to a prescribed pressure value

2. Excitation of the gas A by plasma.

3. Turn plasma off and pump out Gas A

4. Flow gas mixture B to a prescribed pressure value

5. Pump out Gas B.

6. Repeat cycle.

A simulation of this process is carried out to show expected values for process chamber pressure P_{Chb} and showerhead pressures P_{SH} versus time for a short cyclic process. A chamber volume V_{Chb} of 3 liters and a showerhead volume V_{SH} of 0.7 liters are used in the simulations. Values of valve conductance C_{slw} and C_{fst} for this simulation were experimentally determined for the pressure region of operation. For the purpose of this simulation, a simplifying assumption is made that the conductance values are independent of the pressure. This assumption is reasonable since for gas flow in the molecular regime where the Knudson number is greater than 1 (Kn>1), conductance is independent of pressure. For the pressure regions where the gas flow is transitional or viscous, the assumption is reasonable for a small range of pressure around the pressures of interest.

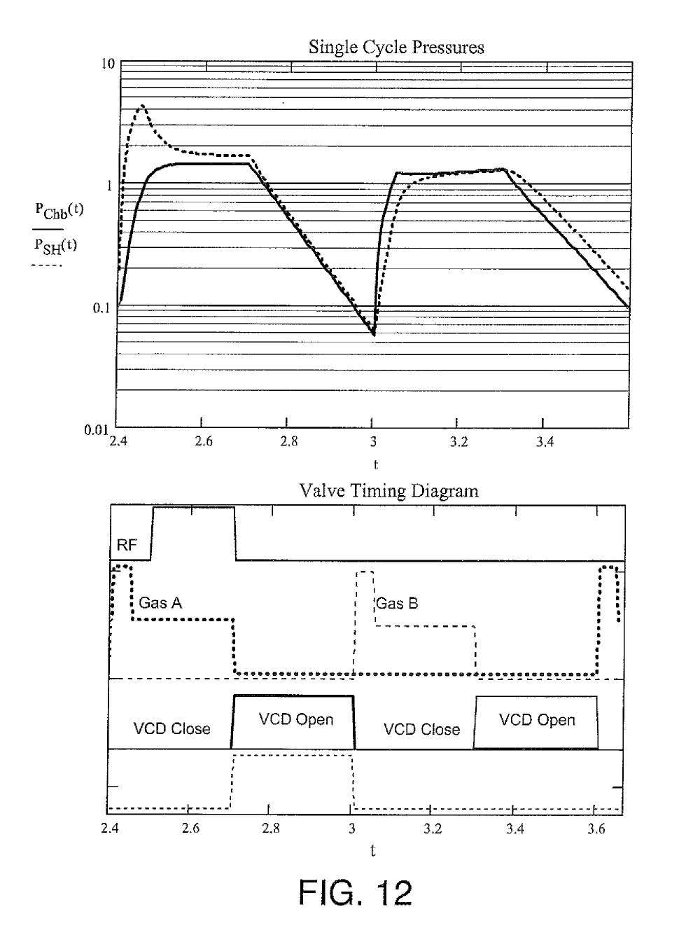

The simulation of the chamber and process chamber pressures are shown in FIG. 12 for one cycle of the process. A cycle time of 1.2 seconds was used for this example, although shorter or longer cycle times could have been chosen with similar results. The sequencing of the valve opening and closings are shown in FIG. 12 for this same cycle. In the figure, “VCD” stands for variable conductance valve. The simulation was started at time zero. Steady state pressure values were reached by the end of the second cycle.

The simulation shows that the chamber pressure is raised 100 milliTorr to a steady state pressure of 1.5 Torr with Gas A in 120 mSec. The RF power is applied to the source 100 mSec from the start of the cycle. The steady state pressure is set by the constant gas reservoir pressure and the fixed values conductance for the gas inject C₁ and C₂. Part A of the process rungs for 200 mSec. Gas A flow then shuts off, RF is shut off and both the VCD valve and showerhead shunt valve is opened to vent the process chamber to a pressure of less than 100 milliTorr.

At 600 mSec into the cycle, the VCD valve is closed, showerhead shut is closed, and Gas B flows though the high and low conductance valves to raise the pressure to a steady state process pressure. This process steps runs 300 milliSec and is then followed by closing of the process gas valves and opening of the VCD valve to vent the chamber of process gas B. The cycle is then completed and the next cycle begins.

This example is illustrative of the capabilities of this disclosure. Based on this disclosure, the chamber module and control system could be easily modified for various processes. Subsequent process steps could be added by simply adding additional gas reservoirs with other gas mixtures or purge gases. The process pressures can be easily adjusted for each process gas by simply setting the gas reservoir pressure to the desired pressures. The time required to transition the gas pressure from high to low is directly related to chamber volumes and conductance values of the values chosen. Each of these can be modified to reach a desired process result or meet a product throughput requirement.

During processing, as shown in the figures, the processing region goes from low pressure to high pressure in repeating cycles. The processing region can be maintained at the high pressure and/or the low pressure for a desired period of time in order for a process to be carried out within the chamber. The conductance valve, on the other hand, rapidly transitions the processing region between the pressure changes. In one embodiment, a single chemical species can be delivered into the processing region as the region undergoes multiple pressure cycles. Alternatively, different chemical species can be introduced into the processing region during multiple pressure cycles. The chemical species can be fluids that are intended to react with the substrate or can be non-reactive gases that are intended to purge the processing region. The amount of time the processing region remains at high pressure and/or low pressure can vary depending upon the particular application. In many embodiments, for instance, the period of time the processing region remains at high pressure or at low pressure may be from about 0.1 seconds to about 2 seconds.

The flow rate of the chemical species into the processing region can also vary dramatically depending upon the particular application. For some applications, for instance, the flow rate of the chemical species may be from about 100 sccm to about 500 sccm.

As demonstrated by the graphs, the time it takes for the processing region to transition from low pressure to high pressure can be less than about 500 ms, such as less than about 300 ms, such as less than about 200 ms, such as from about 50 ms to about 150 ms. The transition from high pressure to low pressure, on the other hand, can be less than about 250 ms, such as less than about 200 ms, such as less than about 50 ms. For instance, as shown in FIG. 5, the transition was about 60 ms in both directions.

Of particular advantage, the change in pressure within the processing region may be by a magnitude of 5 or greater, such as 10 or greater, such as even 100 or greater. At low pressures, for instance, the pressure within the processing region may vary from less than 0.3 Torr, such as less than 0.2 Torr, to greater than 0.8 Torr, such as greater than 1 Torr. Also of particular advantage, the system of the present invention allows for laminar flow of the fluids within the processing region including the flow management region, which can also provide some advantages and benefits.

In the embodiment illustrated in FIG. 1, the processing system 10 is intended to process a single substrate at a time. Other systems, however, can be designed to process multiple substrates at multiple processing stations at the same time.

Various different processes can be carried out in processing systems made in accordance with the present disclosure. For instance, in one embodiment, the processing system can be used to form layers on substrates according to a saturating surface rate mechanism. For example, in one particular embodiment, the processing system can be used to carry out atomic layer deposition. During atomic layer deposition, a chemical species is fed to the processing chamber to form a first monolayer over a substrate. Thereafter, the flow of the first chemical species is ceased and an inert second chemical species, such as a purge gas, is flowed through the processing region to remove any remaining gas or particles not adhering to the substrate. Subsequently, a third chemical species, different from the first, is flowed through the processing region to form a second monolayer on or with the first monolayer. The second monolayer may react with the first monolayer. Additional chemical species can form successive monolayers as desired until a layer with a particular composition and/or thickness has been formed over the substrate. During atomic layer deposition, for instance, each of the chemical species may be pulsed into the processing region and synchronized with the conductance valve. Alternatively, the chemical species may be fed to the chamber under constant flow rate conditions.

Various processes that may be carried out in systems made according to the present disclosure are disclosed, for instance, in U.S. Pat. No. 7,220,685, U.S. Pat. No. 7,132,374, U.S. Pat. No. 6,418,942, U.S. Pat. No. 6,743,300, U.S. Pat. No. 6,783,601, U.S. Pat. No. 6,783,602, U.S. Pat. No. 6,802,137, and U.S. Pat. No. 6,824,620, which are all incorporated herein by reference.

The processing system of the present disclosure, however, can provide various process advantages over many prior art processes. For instance, the use of the conductance valve may allow for chemical species to be introduced and consumed in the processing region in a unique manner. For instance, in one embodiment, a chemical species may be fed to the processing chamber that initially deposits on a surface of a substrate. At the end of a low-pressure cycle, the chemical species can completely or near completely be desorbed from the surface of the substrate. Desorption of the chemical species may create various favorable interactions with the surface of the substrate in order to deposit a layer on the substrate, improve a layer on the substrate, and/or clean the surface of the substrate.

The processing system of the present disclosure can be used to form all different types of layers on semiconductor substrates. For instance, conductive layers, dielectric layers, and semiconductor layers can all be formed on substrates using the system illustrated in FIG. 1.

In one embodiment, the processing system can be placed in communication with a plasma source in order to conduct plasma etching and/or plasma enhanced chemical vapor deposition.

For example, during plasma enhanced CVD processes, both pressure and gas flow can be pulsed during a process. The phase between pulsing of a reacting gas or gases and the pressure would be set to achieve a desired result. For instance, a reacting gas can be pulsed into the processing region so that the reacting gas enters the process region when the conductance valve is in a phase such that the pressure in the process region is at a high. In this manner, the reacting gas may be forced into very small features thereby improving the deposition coverage and rate.

In other embodiments, the gas and pressure timing may be shifted differently to achieve potentially the opposite result. The timing between the gas injection and the pressure variation, for instance, may also be chemistry dependent and as such the system may accommodate changes in the phase of these two primary controls.

The processing system of the present disclosure may also be well suited for use in etching processes such as in any particle removal process that may include the use of a plasma source. During a plasma etching process, for instance, the substrate is exposed to an energized plasma of a gas that is energized by, for example, microwave energy or radio frequency energy. A biasing electrical voltage may be coupled to the energized gas so that charged species (reactive ions) within the gas are energized toward the substrate. In the etching method, recesses shaped as narrow channels, holes, or trenches, are formed in the substrate.

When using the system of the present disclosure in a plasma etching process, the plasma source may be in phase or out of phase with the conduction valve. For instance, a change in the phase between the increase in concentration of a specific etchant reactive gas and pressure could be used to enhance etch rate in small features. The same process may also be used for removal of particles and/or residue from wafer surfaces. These particles or residue may be produced from one or more fabrication processes performed on the substrate. These byproducts of fabrication may become transient particles on the surface of the devices being fabricated and may render these devices semi or non-functional. The system of the present disclosure is well suited to removing these particles and/or residues when present.

These and other modifications and variations to the present invention may be practiced by those of ordinary skill in the art, without departing from the spirit and scope of the present invention, which is more particularly set forth in the appended claims. In addition, it should be understood that aspects of the various embodiments may be interchanged both in whole or in part. Furthermore, those of ordinary skill in the art will appreciate that the foregoing description is by way of example only, and is not intended to limit the invention so further described in such appended claims.

What is claimed:

1. A process for varying the exposure of a substrate to a chemical ambient comprising:
placing a substrate into a processing region of a process chamber, the processing region including an inlet and an outlet for flowing chemical species through the processing region;
flowing a chemical species into the processing region through the inlet;
varying the concentration of the chemical species through the processing region by changing its pressure in the processing region, the processing region pressure being alternated between a high pressure and a low pressure, the high pressure being at least 0.5 Torr greater than the low pressure, and wherein the transition of the processing region pressure from high pressure to low pressure is less than about 500 ms.

2. A process as defined in claim 1, wherein the transition of the processing region pressure from low pressure to high pressure is less than about 500 ms.

3. A process as defined in claim 1, wherein the transitions of the processing region pressure from high pressure to low pressure and from low pressure to high pressure are less than about 250 ms.

4. A process as defined in claim 1, wherein the period of time the processing region is maintained at the high pressure, the time of the transition from the high pressure to the low pressure, the period of time the processing region is maintained at the low pressure, and the time of transition from low pressure to high pressure comprises one pressure cycle and wherein the processing region undergoes multiple pressure cycles while the chemical species is flowing into the processing region.

5. A process as defined in claim 1, wherein the period of time the processing region is maintained at the high pressure, the time of the transition from high pressure to low pressure, the period of time the processing region is maintained at the low pressure, and the time to transition from low pressure to high pressure comprises one pressure cycle and wherein different chemical species are introduced into the processing region during multiple pressure cycles.

6. A process as defined in claim 1, wherein the chemical species reacts with a surface of the substrate according to a saturating surface rate mechanism.

7. A process as defined in claim 1, wherein the processing region is maintained at the high pressure for a first period of time and is maintained at the low pressure for a second period of time and wherein the first period of time and the second period of time is from about 0.1 seconds to about 1 second.

8. A process as defined in claim 1, wherein the chemical species is flowed into the processing region at a flow rate of from about 100 sccm to about 500 sccm.

9. A process as defined in claim 1, wherein the pressure in the processing region is changed by a conductance valve positioned in communication with the outlet of the processing region.

10. A process as defined in claim 1, wherein the processing region has a volume of less than about 2 liters.

11. A process as defined in claim 1, wherein the processing region has a volume of less than about 0.6 liters.

12. A process as defined in claim 9, wherein the conductance valve actuator is comprised of a voice coil actuator in communication with an air bearing.

13. A process as defined in claim 12, wherein the processing region comprises a substrate staging area and at least one slit that extends downwardly from the substrate staging area.

14. A process as defined in claim 13, wherein the slit has a ring-like shape.

15. A process is defined in claim 9, wherein the conductance valve is positioned at the outlet of the processing region and includes a conductance-limiting element that oscillates towards and away from the outlet in order to control pressure in the processing region.

16. A process as defined in claim 15, wherein the conductance-limiting element forms a gap between a surface of the conductance-limiting element and the outlet, the conductance-limiting element oscillating between a first position and a second position, and wherein the gap is less than about 20 microns in the first position and is greater than about 500 microns in the second position.

17. A process as defined in claim 1, further comprising the step of pumping the chemical species from the processing region into an exhaust channel.

18. A process as defined in claim 1, wherein the low pressure in the processing region is maintained below about 2 Torr during the process.

19. A process as defined in claim 1, wherein the chemical species is introduced into the processing region by being pulsed.

20. A process as defined in claim 9, wherein the conductance valve oscillates between an open position and a closed position and wherein the chemical species is introduced into the processing region by being pulsed, the conductance valve being synchronized with the pulses such that the conductance valve is in the opened position at or near the end of a pulse.

21. A process as defined in claim 20, wherein the conductance valve is further synchronized with the pulses of the chemical species such that the conductance valve is at or near the closed position at the beginning of a pulse.

22. A process as defined in claim 1, wherein the processing chamber is in communication with at least one heating device and the process includes the step of heating the substrate within the processing chamber as the chemical species is introduced into the processing region.

23. A process as defined in claim 22, wherein the heating device comprises a heated susceptor positioned below the substrate.

24. A process as defined in claim 1, wherein fluid flow through the processing region is laminar during the process.

25. A process as defined in claim 1, wherein the high pressure is at least ten times greater than the low pressure.

26. A process as defined in claim 12, wherein the processing region comprises a substrate staging area and a flow management region that extends horizontally from the substrate staging area.

27. A process as defined in claim 15, wherein the conductance-limiting element forms a seal against the outlet when in a closed position.

28. A system for processing substrates comprising:
a processing chamber partially defining a processing region and including a substrate pedestal configured to hold a substrate within the processing region, the processing region including an inlet and an outlet; and
a conductance valve in communication with the outlet for controlling pressure in the processing region, the conductance valve including an oscillating conductance-limiting element in operative association with a voice coil actuator.

29. A system as defined in claim 28, wherein the outlet communicates with an exhaust channel, the conductance valve being positioned at the outlet prior to the exhaust channel.

30. A system as defined in claim 29, wherein the processing region comprises a substrate staging area and at least one slit that extends downwardly from the staging area.

31. A system as defined in claim 30, wherein the slit has a ring-like shape.

32. A system as defined in claim 30, wherein the slit has a substantially linear pathway from the substrate staging area to the outlet.

33. A system as defined in claim 30, wherein the conductance-limiting element of the conductance valve covers an end of the slit and oscillates towards and away from the outlet.

34. A system as defined in claim 29, wherein the processing region has a volume of less than about 1 liter.

35. A system as defined in claim 29, wherein the conductance-limiting element of the conductance valve forms a non-sealing engagement with the outlet.

36. A system as defined in claim 35, wherein the conductance-limiting element forms a gap with the outlet, the conductance-limiting element oscillating between a first position and a second position, and wherein the gap is less than about 20 microns in the first position and wherein the gap is greater than about 500 microns in the second position.

37. A system as defined in claim 29, wherein the processing system further comprises a pump for pumping gases and volatile components out of the processing region, the pump being positioned downstream from the conductance valve.

38. A system as defined in claim 28, wherein the system further comprises a heating device in communication with the process chamber for heating substrates contained on the substrate pedestal.

39. A system for processing substrates comprising:
a process chamber partially defining a processing region and including a substrate pedestal configured to hold a substrate within the processing region, the processing region including an inlet and an outlet;
a heating device in communication with the processing chamber for heating substrates contained on the substrate pedestal; and
a variable conductance valve positioned at the outlet, the variable conductance valve being configured to control pressure in the processing region; and
wherein the processing region has a substantially linear pathway from a substrate held on the substrate pedestal to the outlet of the processing region, the processing region having a volume of less than about 2 liters.

40. A system as defined in claim 39, wherein the processing region comprises a substrate staging area and at least one slit that extends downwardly from the staging area.

41. A system as defined in claim 39, wherein the conductance valve includes an oscillating or rotating conductance-limiting element in operative association with a voice coil actuator.

42. A system as defined in claim 39, wherein the conductance-limiting element forms a gap with the outlet, the conductance-limiting element oscillating between a first position and a second position, and wherein the gap is less than about 20 microns in the first position and wherein the gap is greater than about 500 microns in the second position.

43. A system as defined in claim 39, wherein the system further comprises a pump for pumping gases out of the processing chamber, the pump being positioned downstream from the conductance valve.

44. A system as defined in claim 39, wherein the system further comprises a heating device in communication with the process chamber for heating substrates contained on the substrate holder.

45. A system as defined in claim 39, wherein the substantially linear pathway extends in a horizontal direction from the substrate holder such that the linear pathway is substantially parallel with a substrate positioned on the substrate holder.

46. A system as defined in claim 39, further comprising a showerhead gas diffusion plate in communication with the inlet, the showerhead gas diffusion plate separating the processing region from a gas plenum area, the system further including a high conductance port controlled by a fast acting on/off valve, the conductance port controlling gas flow from the gas plenum into the showerhead gas diffusion plate.

47. A system as defined in claim 39, wherein the inlet is in communication with one or more process gas reservoirs, each reservoir being maintained at a constant fixed pressure by a closed loop control system.

48. A system as defined in claim 47, wherein the system further includes a controller which controls the closed loop control system, the fixed pressure within each reservoir being determined by a process recipe inputted into the controller.

49. A gas injection system for feeding one or more process gases into a process chamber comprising:
a fixed pressure reservoir that includes at least a first line and a second line that are in fluid communication with a process chamber, each line being in communication with an on/off valve and with a respective and different conductance valve that are configured to provide a step flow rate control.

50. A method for calibrating a variable conductance valve, the variable conductance valve including an oscillating or rotating conductance-limiting element in operative association with an actuator, the variable conductance valve being calibrated by driving the actuator to a stop position while monitoring a drive current and an encoder position, and wherein when a slope of the drive current versus a position curve equals a predetermined value, the encoder is recorded and used to reset a zero position of the conductance valve.

51. A method as defined in claim 50, wherein the conductance-limiting element is in association with at least three actuators, each actuator independently undergoing the calibration method defined in claim 50.
